(19) United States
(12) Patent Application Publication
(10) Pub. No.: US 2026/0101609 A1
(43) Pub. Date: Apr. 9, 2026

(54) LIGHT-EMITTING DIODE CHIPS WITH OPTICALLY PUMPED QUANTUM WELL STRUCTURES

(71) Applicant: CreeLED, Inc., Durham, NC (US)

(72) Inventors: Joseph G. Sokol, Durham, NC (US); Michael Check, Holly Springs, NC (US); David Suich, Durham, NC (US); Colin Blakely, Raleigh, NC (US); Robert Wilcox, Rolesville, NC (US); Andre Pertuit, Raleigh, NC (US)

(21) Appl. No.: 18/909,243

(22) Filed: Oct. 8, 2024

(51) Int. Cl. H01L 33/06; H01L 33/08; H01L 33/38

(52) U.S. Cl. CPC H10H 20/812; H10H 20/813; H10H 20/8312

(57) ABSTRACT

Light-emitting diode (LED) devices and more particularly LED chips with optically pumped quantum well structures are disclosed. LED chips include electrically pumped quantum well structures positioned proximate p-n junctions, and optically pumped quantum well structures positioned to receive photons of light generated by the electrically pumped quantum well structures and re-emit light having longer peak wavelengths. Aggregate emissions may include broader emission spectrums. Moreover, aggregate emissions may predominately be provided by light from the electrically pumped quantum well structures while light from the optically pumped quantum well structures may provide wavelengths that appear brighter to the human eye to increase luminous flux. Various LED chip structures are disclosed that provide arrangements for flip-chip structures that position optically pumped quantum well structures in intended light paths while reducing interactions with electrical paths within LED chips

### FIELD OF THE DISCLOSURE

The present disclosure relates to light-emitting diode (LED) devices, and more particularly to LED chips with optically pumped quantum well structures.

### BACKGROUND

Light-emitting diodes (LEDs) are widely used in consumer and commercial applications. Continued developments in LED technology have resulted in highly efficient and mechanically robust light sources arranged to output emissions in the visible spectrum and beyond. These attributes, coupled with the long service life of solid state devices, have enabled a variety of new lighting applications.

LEDs generally include an n-type region and a p-type region that form a p-n junction, and an active region that is located proximate the p-n junction.

The active region is typically fabricated from a material having a suitable bandgap such that electron-hole recombination results in the generation of light when current is passed through. Attempts to improve light output and other electrical characteristics of LEDs have included providing differing configurations of the n-type regions, p-type regions, and active regions. Such attempts have, for example, included the use of single and/or double heterostructure epitaxial structures. Similarly, epitaxial structures that include one or more quantum wells have also been fabricated. While such attempts have made improvements to the electrical characteristics of Group III nitride-based devices, further improvements may still be achieved.

As advancements in modern LED technology progress, the art continues to seek improved LEDs having desirable illumination characteristics.

### SUMMARY

The present disclosure relates to light-emitting diode (LED) devices, and more particularly to LED chips with optically pumped quantum well structures. LED chips include electrically pumped quantum well structures positioned proximate p-n junctions, and optically pumped quantum well structures positioned to receive photons of light generated by the electrically pumped quantum well structures and re-emit light having longer peak wavelengths. Aggregate emissions may include broader emission spectrums. Moreover, aggregate emissions may predominately be provided by light from the electrically pumped quantum well structures while light from the optically pumped quantum well structures may provide wavelengths that appear brighter to the human eye to increase luminous flux. Various LED chip structures are disclosed that provide arrangements for flip-chip structures that position optically pumped quantum well structures in intended light paths while reducing interactions with electrical paths within LED chips.

In one aspect, an LED chip comprises: a substrate; an n-type layer; a p-type contact layer; a first quantum well structure between the n-type layer and the p-type contact layer, the first quantum well structure configured to provide light having a first peak wavelength; and a second quantum well structure between the first quantum well structure and the substrate, the second quantum well structure configured to absorb a portion of the light having the first peak wavelength and generate light having a second peak wavelength, the second peak wavelength being longer than the first peak wavelength. In certain embodiments, the first quantum well structure comprises a first multiple quantum well and the second quantum well structure comprises a second multiple quantum well. In certain embodiments, the first peak wavelength is in a range from 430 nanometers (nm) to 480 nm, and the second peak wavelength is in a range from 480 nm to 570 nm.

In certain embodiments: the n-type layer, the p-type contact layer, the first quantum well structure, and the second quantum well structure are part of an epitaxial structure; the substrate is a growth substrate for the epitaxial structure; and a surface of the substrate opposite the epitaxial structure forms a primary light-emitting surface. In certain embodiments: the first quantum well structure is configured to provide a first emission intensity of the light having the first peak wavelength that exits the primary light-emitting surface; the second quantum well structure is configured to provide a second emission intensity of the light having the second peak wavelength that exits the primary light-emitting surface; and the first emission intensity is greater than the second emission intensity.

The LED chip may further comprise an undoped layer between the second quantum well structure and the n-type layer. The LED chip may further comprise an additional undoped layer between the second quantum well structure and the substrate.

In certain embodiments, the n-type layer is a first n-type layer that is between the second quantum well structure and the substrate, and a second n-type layer is between the second quantum well structure and the first quantum well structure. The LED chip may further comprise an n-contact interconnect that extends through the p-type contact layer, the first quantum well structure, and a portion of the second n-type layer, wherein the second quantum well structure is in a portion of the second n-type layer that is between the first n-type layer and a termination of the n-contact interconnect within the second n-type layer.

In certain embodiments, the second quantum well structure forms a superlattice structure for the first quantum well structure.

The LED chip may further comprise a third quantum well structure between the second quantum well structure and the substrate, wherein the third quantum well structure is configured to absorb a portion of the light having the first peak wavelength and generate light having a third peak wavelength, the third peak wavelength is longer than the first peak wavelength, and the third peak wavelength is different than the second peak wavelength. In certain embodiments, the third quantum well structure and the second quantum well structure are separated by an undoped layer. In certain embodiments, the first peak wavelength is in a range from 430 nanometers (nm) to 480 nm, the second peak wavelength is in a range from 480 nm to 520 nm, and the third peak wavelength is in a range from 520 nm to 570 nm. In certain embodiments, first peak wavelength is in a range from 430 nanometers (nm) to 450 nm, the second peak wavelength is in a range from 450 nm to 480 nm, and the third peak wavelength is in a range from 480 nm to 570 nm. In certain embodiments, the first peak wavelength is in a range from 100 nanometers (nm) to 400 nm, the second peak wavelength is in a range from 430 nm to 480 nm, and the third peak wavelength is in a range from 480 nm to 570 nm. In certain embodiments, the second quantum well structure forms a superlattice structure for the first quantum well structure, and the third quantum well structure is between the second quantum well structure and the substrate.

In another aspect, an LED chip comprises: an epitaxial structure comprising: an n-type layer; a p-type contact layer; a first quantum well structure between the n-type layer and the p-type contact layer, the first quantum well structure configured to provide light having a first peak wavelength; and a second quantum well structure configured to absorb a portion of the light having the first peak wavelength and generate light having a second peak wavelength, the second peak wavelength being longer than the first peak wavelength, the first quantum well structure positioned between the p-type contact layer and the second quantum well structure; a p-contact electrically connected to the p-type contact layer; and an n-contact electrically connected to the n-type layer, the p-contact and the n-contact being arranged on a same side of the epitaxial structure. In certain embodiments, a primary light-emitting surface of the LED chip is formed on a side of the epitaxial structure that is opposite the p-contact and the n-contact. In certain embodiments, the second quantum well structure is positioned between the primary light-emitting surface and the first quantum well structure. The LED chip may further comprise a third quantum well structure between the primary light-emitting surface and the first quantum well structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a portion of an exemplary light-emitting diode (LED) chip with a first quantum well structure configured for electrical pumping and a second quantum well structure configured to be optically pumped from light generated by the first quantum well structure.

FIG. 2 is an emission plot representing an exemplary luminous output of the LED chip of FIG. 1.

FIG. 3 is a general band diagram of the LED chip of FIG. 1 representing bandgap profiles of the first quantum well structure and the second quantum well structure.

FIG. 4 is a cross-sectional view of a portion of an LED chip that is similar to the LED chip of FIG. 1 and where the second quantum well structure is positioned in a different location of the epitaxial structure.

FIG. 5 is a cross-sectional view of a portion of an LED chip that is similar to the LED chip of FIG. 1 and where the second quantum well structure is positioned to replace the superlattice structure of FIG. 1.

FIG. 6 is a cross-sectional view of a portion of an LED chip that is similar to the LED chip of FIG. 1 and further includes a third quantum well structure.

FIG. 7 is a cross-sectional view of a portion of an LED chip that is similar to the LED chip of FIG. 6 for embodiments where the second quantum well structure and the third quantum well structure are separated from one another within the epitaxial structure.

FIG. 8 is a cross-sectional view of a portion of an LED chip that is similar to the LED chip of FIG. 5 for embodiments that include the third quantum well structure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to LED chips with optically pumped quantum well structures. LED chips include electrically pumped quantum well structures positioned proximate p-n junctions, and optically pumped quantum well structures positioned to receive photons of light generated by the electrically pumped quantum well structures and re-emit light having longer peak wavelengths. Aggregate emissions may include broader emission spectrums. Moreover, aggregate emissions may predominately be provided by light from the electrically pumped quantum well structures while light from the optically pumped quantum well structures may provide wavelengths that appear brighter to the human eye to increase luminous flux. Various LED chip structures are disclosed that provide arrangements for flip-chip structures that position optically pumped quantum well structures in intended light paths while reducing interactions with electrical paths within LED chips.

An LED chip typically includes an active LED structure or region that may have many different semiconductor layers arranged in various ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, current-spreading layers, and light extraction layers and elements. The active layer may include a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. In certain applications, UV LEDs may also be provided with one or more lumiphoric materials to provide LED packages with aggregate emissions having a broad spectrum and improved color quality for visible light applications. Near-IR and/or IR wavelengths for LED structures of the present disclosure may have wavelengths above 700 nm, such as in a range from 750 nm to 1100 nm, or more.

The present disclosure may be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In certain embodiments, the emitted radiation comprises visible light such as blue and/or green LEDs with or without lumiphoric materials. In other embodiments, the emitted radiation may comprise nonvisible light. In certain embodiments, a “light-transmissive” material may be configured to transmit at least 50% of emitted radiation of a desired wavelength.

In active LED structures within LED chips, photons are generated when an electron traverses from the higher energy conduction band to the lower energy valence band at a quantum well structure, typically located proximate a p-n junction. The difference in energy is released as a photon or through other non-radiative means. For release of photons, the corresponding wavelength is dependent on the bandgap energy between the conduction and valence bands. Such recombination and photon generation occurs when the active LED structure is electrically activated. It is also possible for a photon of higher energy to be absorbed at a quantum well structure and push an electron from a valence band into a corresponding conduction band creating a hole in the valence band. Then, that hole may be filled by a new electron dropping in energy, releasing a photon with a wavelength corresponding to this specific bandgap. Such a mechanism where absorption of a photon of higher energy generates another photon is referred to herein as optical pumping. In this regard, a quantum well structure configured to absorb a recipient photon and provide another photon of a different wavelength is referred to herein as an optically pumped quantum well structure. Moreover, a quantum well structure that generates photons in response to electrical activation may be referred to as an electrically pumped quantum well structure and/or an electrically pumped active LED structure. As used herein, a quantum well structure may refer to an epitaxial layer sequence that includes a well layer and one or more associated barrier layers having a larger bandgap than the well layer. Quantum well structures with a single well layer may be referred to as a single quantum well structure while those with multiple well layers may be referred to as a multiple quantum well (MQW) structure.

According to aspects of the present disclosure, luminous flux for LED chips is improved by combining an electrically pumped quantum well structure with an optically pumped quantum well structure within a common epitaxial structure of an LED chip. The optically pumped quantum well structure may be configured to absorb a portion of light generated by the electrically pumped quantum well structure and provide light of a different wavelength. For example, an exemplary LED chip may include a first quantum well structure positioned proximate a p-n junction and configured to generate light of a first peak wavelength (e.g., in a range from 430 nm to 480 nm). The LED chip may further include a second quantum well structure that is configured to receive a portion of light of the first peak wavelength and provide light of second peak wavelength (e.g., in a range from 480 nm to 570 nm). In various aspects, the second quantum well structure is configured to provide a relatively smaller amount of light having the second peak wavelength. Accordingly, the LED chip may still primarily emit light having the first peak wavelength and the smaller amount of light having the second peak wavelength may increase the luminous flux by providing a portion of light in the green spectrum that appears brighter to the human eye. In various aspects, the second quantum well structure may be positioned in various locations, such as in undoped layers and/or proximate the first quantum well structure. In further aspects, the second quantum well structure may be positioned between the first quantum well structure and a growth substrate for an LED chip configured for flip-chip mounting. Such an arrangement positions the second quantum well structure in the light path from the first quantum well structure through the growth substrate that defines a primary emission direction for the LED chip.

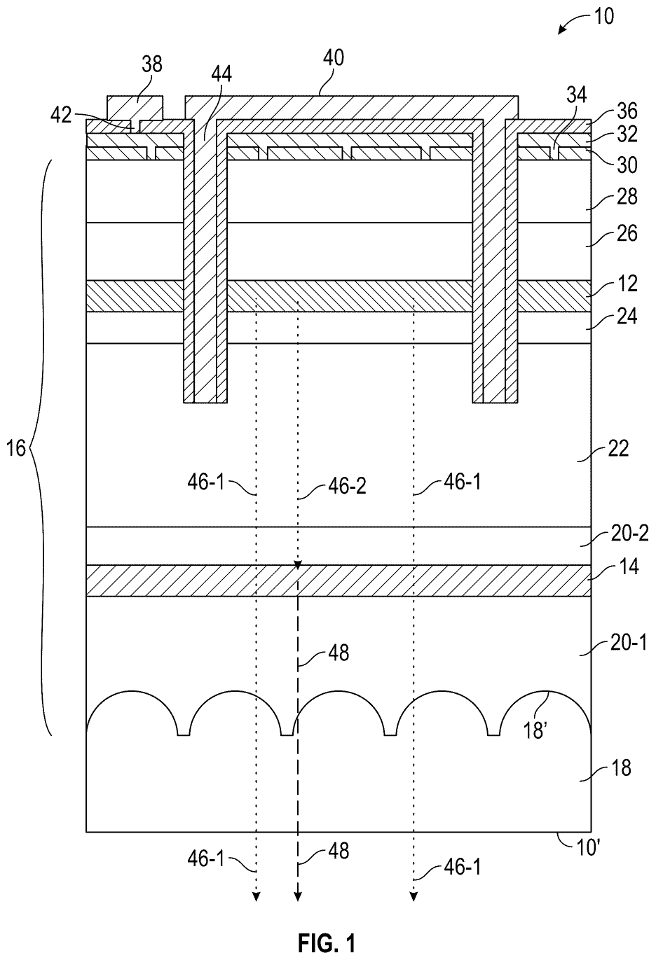

FIG. 1 is a cross-sectional view of a portion of an exemplary LED chip 10 with a first quantum well structure 12 configured for electrical pumping and a second quantum well structure 14 configured to be optically pumped from light generated by the first quantum well structure 12. The first quantum well structure 12 and the second quantum well structure 14 may each embody a single quantum well or a MQW structure. The LED chip 10 includes an epitaxial structure 16. As used herein, an epitaxial structure refers to a sequence of layers that are epitaxially deposited by way of various deposition techniques, such as metal organic chemical vapor deposition (MOCVD). In certain aspects, the epitaxial structure 16 includes various layers of GaN-based semiconductor layers on or over a substrate 18, which may also be referred to as a growth substrate. The substrate 18 may comprise any material compatible for growth of the epitaxial structure 16, such as sapphire in the example where the epitaxial structure 16 is formed of Group III nitride material layers. In other embodiments, the substrate 18 may comprise GaN, silicon (Si), silicon carbide or other epitaxially compatible substrate materials. It is to be appreciated, however, that the substrate 18 may be subsequently removed after growth of the epitaxial structure 16 in certain LED chip structures. In the example provided by FIG. 1, the substrate 18 remains as part of a flip-chip structure where the LED chip 10 is subsequently inverted for mounting such that the substrate 18 is up and forms a primary light-emitting surface 10′ of the LED chip 10. The substrate 18 may have one or more surfaces that are shaped, textured, or patterned to enhance light extraction. In certain embodiments, the substrate 18 is light transmissive (preferably transparent) and may include a patterned surface 18′ that is proximate the epitaxial structure 16 and includes multiple recessed and/or raised features.

The epitaxial structure 16 may include undoped layers 20-1, 20-2, such as undoped layers of GaN (u-GaN) on the substrate 18. The undoped layers 20-1, 20-2 may also be referred to as unintentionally doped layers since some residual impurities present during epitaxial growth may inadvertently be incorporated. Even when unintentionally doped, the undoped layers 20-1, 20-2 would have far lower impurity concentrations than other layers that are intentionally doped with n-type or p-type impurities. The undoped layers 20-1, 20-2 are effectively not part of the electrical pathway when the LED chip 10 is electrically activated. The undoped layers 20-1, 20-2 are formed to provide a smooth surface with reduced pits and other lattice defects that is conducive for improved growth of the remaining portions of the epitaxial structure 16. By forming the second quantum well structure 14 on a smooth surface provided by the undoped layer 20-1, thickness uniformity and other layer characteristics of the second quantum well structure 14 may be precisely controlled. Moreover, the undoped layers 20-1, 20-2 have improved stress and/or strain profiles relative to doped layers, thereby providing further control of uniformity of the second quantum well structure 14.

The epitaxial structure 16 may further include an n-type layer 22 or n-contact layer, such as a silicon doped layer of GaN (n-GaN or Si-GaN), a superlattice structure 24, or SLS, that may include alternating layers of Si-GaN and/or InGaN; a p-type layer 26 doped with a p-type impurity such as magnesium (p-AlGaN or Mg-AlGaN); and a p-type contact layer 28 that is also doped with a p-type impurity, such as p-GaN. The superlattice structure 24 provides strain relief for the first quantum well structure 12. In certain aspects, the superlattice structure 24 may also include a well layer with an associated barrier layer.

However, the corresponding bandgap of the superlattice structure 24 is tuned to shorter wavelengths, such as violet or ultraviolet, than the first quantum well structure 12 to avoid interaction with light generated by the first quantum well structure 12. It is understood that the epitaxial structure 16 may further include additional layers, such as various capping, cladding, spacer, and/or buffer layers. In general terms, an active LED structure may refer to a portion of the epitaxial structure 16 that forms a p-n junction and is electrically active for electrical pumping of the first quantum well structure 12, such as the n-type layer 22, the first quantum well structure 12, and the p-type layer 26. The superlattice structure 24 and the p-type contact layer 28 may also be considered part of the active LED structure.

As mentioned above, the LED chip 10 may be configured as a flip-chip structure where the substrate 18 forms the primary light-emitting surface 10′ of the LED chip 10. Light generated by the first quantum well structure 12 is typically emitting omnidirectionally. In order to redirect light traveling away from the first quantum well structure 12, the LED chip 10 may include a reflective structure on the p-type contact layer 28. In FIG. 1, the reflective structure is formed by a dielectric reflective layer 30 and a metal reflective layer 32 that serve to redirect light toward the substrate 18.

The dielectric reflective layer 30 is provided on portions of the p-type layer 26 and/or the p-type contact layer 28. The dielectric reflective layer 30 may comprise many different materials and preferably comprises a material that presents an index of refraction step with the material of the epitaxial structure 16 to promote total internal reflection (TIR) of light. Light that experiences TIR is redirected without experiencing absorption or loss and can thereby contribute to useful or desired LED chip emission. In certain embodiments, the dielectric reflective layer 30 comprises a material with an index of refraction lower than the index of refraction of the epitaxial structure 16. In certain embodiments, the dielectric reflective layer 30 comprises silicon dioxide (SiO₂) and/or silicon nitride (SiN). It is understood that many dielectric materials can be used such as SiN, SiNx, Si₃N₄, Si, germanium (Ge), SiO₂, SiOx, titanium oxide (TiOx), titanium dioxide (TiO₂), tantalum pentoxide (Ta₂O₅), indium tin oxide (ITO), magnesium oxide (MgOx), zinc oxide (ZnO), and combinations thereof. In certain embodiments, the dielectric reflective layer 30 comprises multiple alternating layers of different dielectric materials, e.g., alternating layers of SiO₂ and TiOx that symmetrically repeat or are asymmetrically arranged to form an asymmetric distributed Bragg reflector.

The metal reflective layer 32 is on the dielectric reflective layer 30 such that the dielectric reflective layer 30 is between the epitaxial structure 16 and the metal reflective layer 32. The metal reflective layer 32 forms a structure configured to reflect any light that may pass through the dielectric reflective layer 30. Exemplary materials for the metal reflective layer 32 include silver (Ag), indium (In), tin (Sn), zinc (Zn), or tin-silver-copper (SAC). As illustrated, the metal reflective layer 32 may include one or more reflective layer interconnects 34 that provide electrically conductive paths through the dielectric reflective layer 30 to the p-type contact layer 28. In certain embodiments, the reflective layer interconnects 34 comprise reflective layer vias. In certain embodiments, the reflective layer interconnects 34 comprise the same material as the metal reflective layer 32 and are formed at the same time as the metal reflective layer 32. In other embodiments, the reflective layer interconnects 34 may comprise a different material than the metal reflective layer 32.

A passivation layer 36 may be included on the metal reflective layer 32. The passivation layer 36 may further be arranged on portions of the dielectric reflective layer 30 that are uncovered by the metal reflective layer 32. The passivation layer 36 protects and provides electrical insulation for the LED chip 10 and may comprise many different materials, such as a dielectric material. In certain embodiments, the passivation layer 36 is a single layer, and in other embodiments, the passivation layer 36 comprises a plurality of layers. Suitable materials for the passivation layer 36 include but are not limited to SiN, SiNx, and/or Si₃N₄.

In FIG. 1, the LED chip 10 comprises a p-contact 38 and an n-contact 40 that are arranged on the passivation layer 36 and are configured to provide electrical connections with different portions of the epitaxial structure 16. The p-contact 38, which may also be referred to as an anode contact, may comprise one or more p-contact interconnects 42 that extend through the passivation layer 36 to the metal reflective layer 32 to provide an electrical path to the p-type contact layer 28. In certain embodiments, the one or more p-contact interconnects 42 comprise one or more p-contact vias. The n-contact 40, which may also be referred to as a cathode contact, is electrically coupled to the n-type layer 22 by way of one or more n-contact interconnects 44 that extend through the passivation layer 36, the dielectric reflective layer 30, the metal reflective layer 32, the p-type contact layer 28, the p-type layer 26, the first quantum well structure 12, and the superlattice structure 24. In certain embodiments, the one or more n-contact interconnects 44 may be referred to as one or more n-contact vias. Openings for the n-contact interconnects 44 may be formed in various etching steps before the passivation layer 36 is formed such that the passivation layer 36 extends along these openings to electrically insulate portions of the n-contact interconnects 44 above the n-type layer 22.

As described above, the LED chip 10 may embody a flip-chip structure where the substrate 18 forms the primary light-emitting surface 10′ of the LED chip 10. The p-contact 38 is electrically connected to the p-type contact layer 28 from a same side of the epitaxial structure 16 from which the n-contact 40 is electrically connected to the n-type layer 22. For flip-chip mounting, the LED chip 10 is inverted so that the p-contact 38 and the n-contact 40 are mechanically and electrically attached to electrical connections of a mounting surface, such as traces of a printed circuit board. When electrically activated, the first quantum well structure 12 generates light 46-1, 46-2 having a first peak wavelength. By positioning the second quantum well structure 14 between the first quantum well structure 12 and the substrate 18, the second quantum well structure 14 is in the light path for the light 46-1, 46-2 of the first peak wavelength exiting the LED chip 10. Certain portions of the light 46-1 of the first peak wavelength may pass through the second quantum well structure 14 and exit the primary light-emitting surface 10′. Other portions of the light 46-2 of the first peak wavelength may optically pump the second quantum well structure 14 and provide light 48 having a second peak wavelength that is longer than the first peak wavelength. In certain embodiments, the relative amounts of the light 46-1 of the first peak wavelength exiting the LED chip 10 may be much greater than amounts of the light 46-2 of the second peak wavelength exiting the LED chip 10.

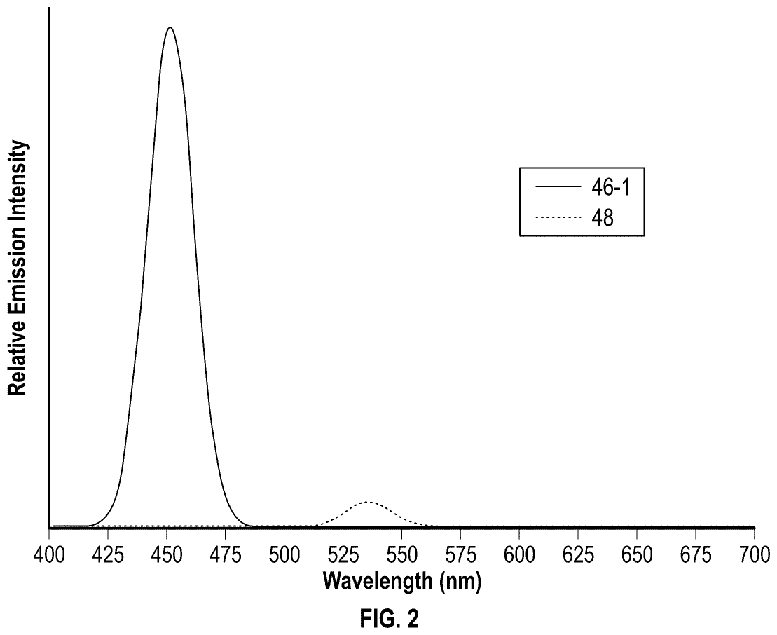

FIG. 2 is an emission plot representing an exemplary luminous output of the LED chip 10 of FIG. 1. The x-axis represents wavelength in nanometers while the y-axis represents relative emission intensity. As illustrated, the light 46-1 having the first peak wavelength is provided with much greater emission intensity than the light 48 having the second peak wavelength. As described above, the light 48 may be provided in a wavelength range, such as 480 nm to 570 nm, that is better perceived by the human eye. Accordingly, relatively small amounts of the light 48 of the second peak wavelength may significantly improve overall luminous flux.

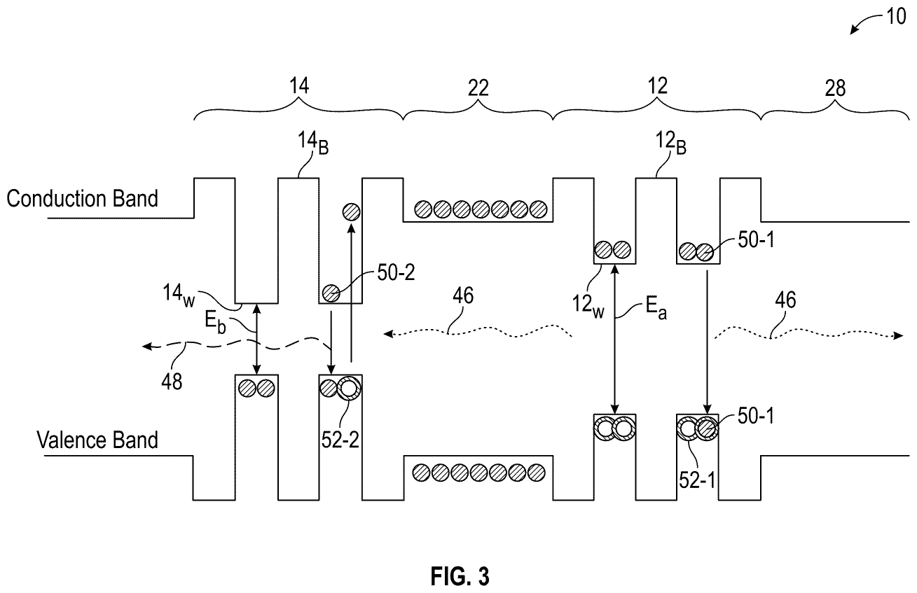

FIG. 3 is a general band diagram of the LED chip 10 of FIG. 1 representing bandgap profiles of the first quantum well structure 12 and the second quantum well structure 14. FIG. 3 also includes band diagram relationships for the n-type layer 22 and the p-type contact layer 28, while other layers of the LED chip 10 are omitted for illustrative purposes. In the example of FIG. 3, the first quantum well structure 12 is generally represented as an MQW structure with multiple wells 12_{W} and corresponding barriers 12_{B}. In a similar manner, the second quantum well structure 14 is generally represented as an MQW structure with multiple wells 14_{W} and corresponding barriers 14_{B}. While two wells are illustrated for the first quantum well structure 12 and the second quantum well structure 14, the first quantum well structure 12 and/or the second quantum well structure 14 may include any number of wells from 2 to 30 or more, depending on the embodiment. Moreover, the first quantum well structure 12 and the second quantum well structure 14 may have different numbers of wells. When the LED chip 10 is electrically activated, electrons 50-1 from the conduction band combine with holes 52-1 from the valence band proximate the first quantum well structure 12, thereby releasing light 46 of the first peak wavelength. The bandgap energy Eₐ of the wells 12_{W} of the first quantum well structure 12 determine the first peak wavelength. When a photon of the light 46 of the first peak wavelength is absorbed in the valence band of the second quantum well structure 14, holes 52-2 are generated that may be subsequently filled by electrons 50-2 from the conduction band of the second quantum well structure 14, thereby releasing the light 48 of the second peak wavelength. The bandgap energy E_{b} of the wells 14_{W} of the second quantum well structure 14 determine the second peak wavelength.

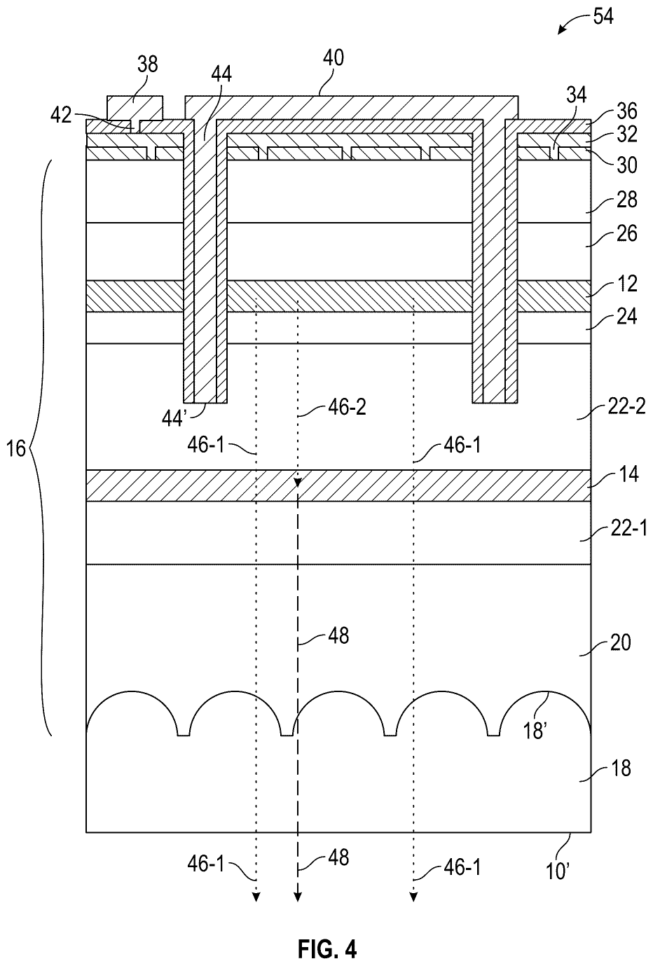

FIG. 4 is a cross-sectional view of a portion of an LED chip 54 that is similar to the LED chip 10 of FIG. 1 and where the second quantum well structure 14 is positioned in a different location of the epitaxial structure 16. Instead of being positioned in the undoped layer 20, the second quantum well structure 14 may reside in a doped portion of the epitaxial structure 16. In FIG. 4, the n-type layer 22 as described for FIG. 1 is split into a first n-type layer 22-1 and a second n-type layer 22-2 on either side of the second quantum well structure 14. As illustrated, the n-contact interconnects 44 may extend into and terminate within the second n-type layer 22-2. The second quantum well structure 14 is positioned between first n-type layer 22-1 and the second n-type layer 22-2 such that a termination 44′ of the n-contact interconnects 44 is separated from the second quantum well structure 14 by continuous portions of the second n-type layer 22-2. In this manner, when the LED chip 54 is electrically activated, the second quantum well structure 14 may be positioned outside most of the current path.

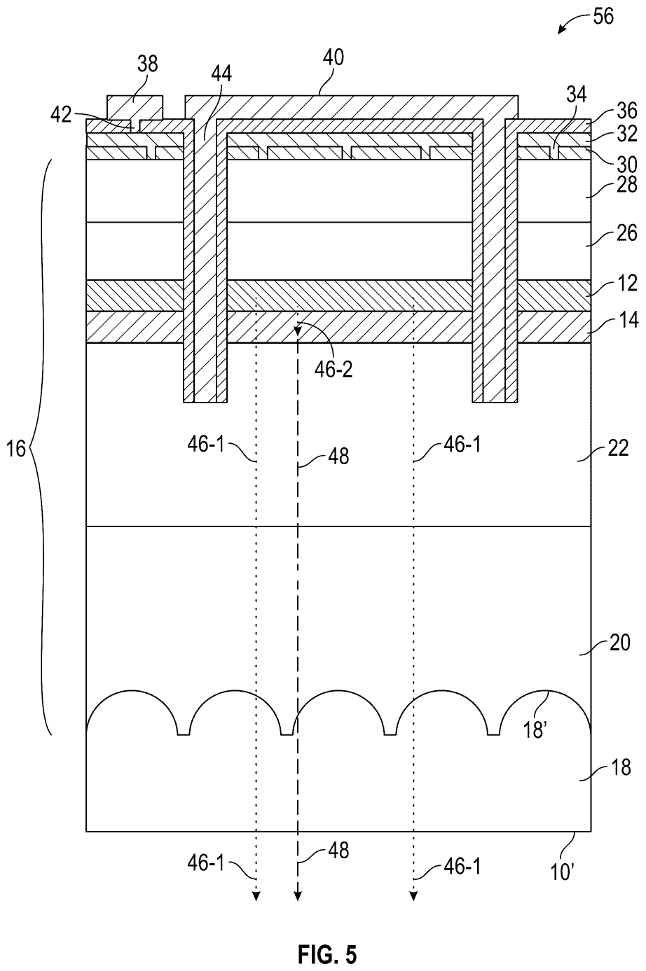

FIG. 5 is a cross-sectional view of a portion of an LED chip 56 that is similar to the LED chip 10 of FIG. 1 and where the second quantum well structure 14 is positioned to replace the superlattice structure 24 of FIG. 1. In this arrangement, the second quantum well structure 14 may further function as a superlattice structure for the first quantum well structure 12. In the LED chip 56, the first quantum well structure 12 and the second quantum well structure 14 are adjacent one another and, in some embodiments, the first quantum well structure 12 is directly on the second quantum well structure 14. The second quantum well structure 14 thereby forms a dual-purpose layer that provides strain release for growing the first quantum well structure 12 in a similar manner as the superlattice structure 24 of FIG. 1 while also providing the optically pumped generation of the light 48 of the second peak wavelength. Moreover, the overall thickness of the LED chip 56 is not increased to avoid potential bowing or warping. While the second quantum well structure 14 is positioned within an electrical path of the LED chip 56, it is still positioned on an opposite side of the first quantum well structure 12 relative to the p-type layer 26 and the p-type contact layer 28. In this regard, the second quantum well structure 14 is positioned away from the p-side of the epitaxial structure 16 to reduce and/or avoid electrically pumped hole recombination.

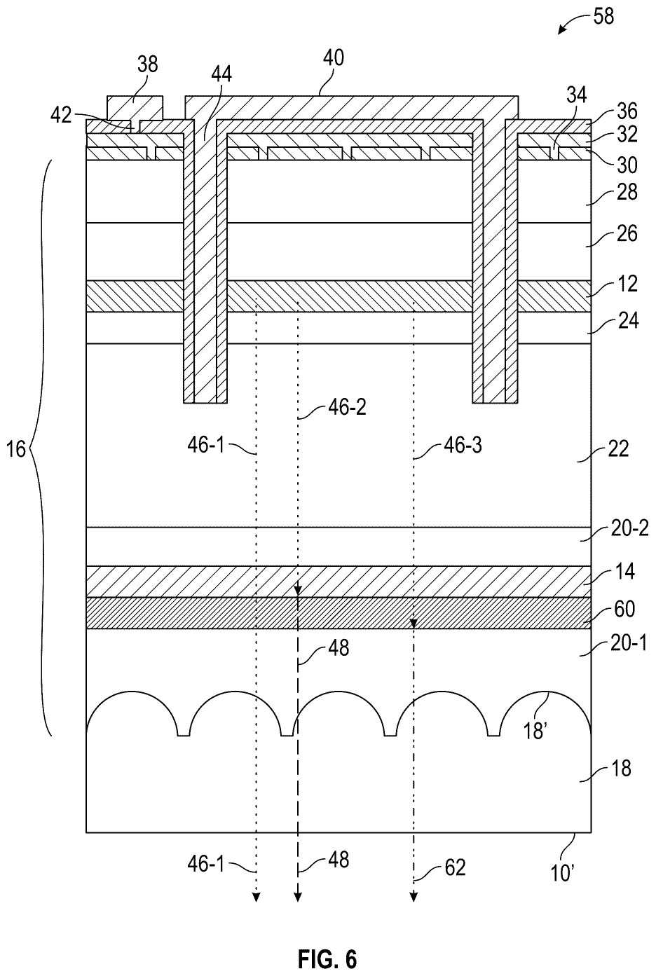

FIG. 6 is a cross-sectional view of a portion of an LED chip 58 that is similar to the LED chip 10 of FIG. 1 and further includes a third quantum well structure 60. The third quantum well structure 60 may be configured to be optically pumped by photons of the first quantum well structure 12 in a similar manner as the second quantum well structure 14. The third quantum well structure 60 may be configured to generate light 62 having a third peak wavelength that is longer than light 46-1 to 46-3 of the first peak wavelength. Moreover, the light 62 of the third peak wavelength may be different than the light 48 of the second peak wavelength to provide a broader aggregate emission spectrum from the LED chip 58. For example, the light 48 of the second peak wavelength may be in a range from 480 nm to 520 nm, and the light 62 of the third peak wavelength may be in a range from 520 nm to 570 nm. In another example, the light 46-1 to 46-3 of the first peak wavelength may be in a range from 430 nm to 450 nm, the light 48 of the second peak wavelength may be in a range from 450 nm to 480 nm, and the light 62 of the third peak wavelength may be in a range from 480 nm to 570 nm. In another example, the light 46-1 to 46-3 of the first peak wavelength may be nonvisible light in the ultraviolet range (e.g., 100 nm to 400 nm), the light 48 of the second peak wavelength may be in a range from 430 nm to 480 nm, and the light 62 of the third peak wavelength may be in a range from 480 nm to 570 nm. The first, second, and third quantum well structures 12, 14, 60 may have a same number of wells or a different number of wells, depending on the embodiment. In the LED chip 58, both the second quantum well structure 14 and the third quantum well structure 60 are positioned between the first undoped layer 20-1 and the second undoped layer 20-2. In certain embodiments, the second quantum well structure 14 may directly contact the third quantum well structure 60 for ease of manufacturing.

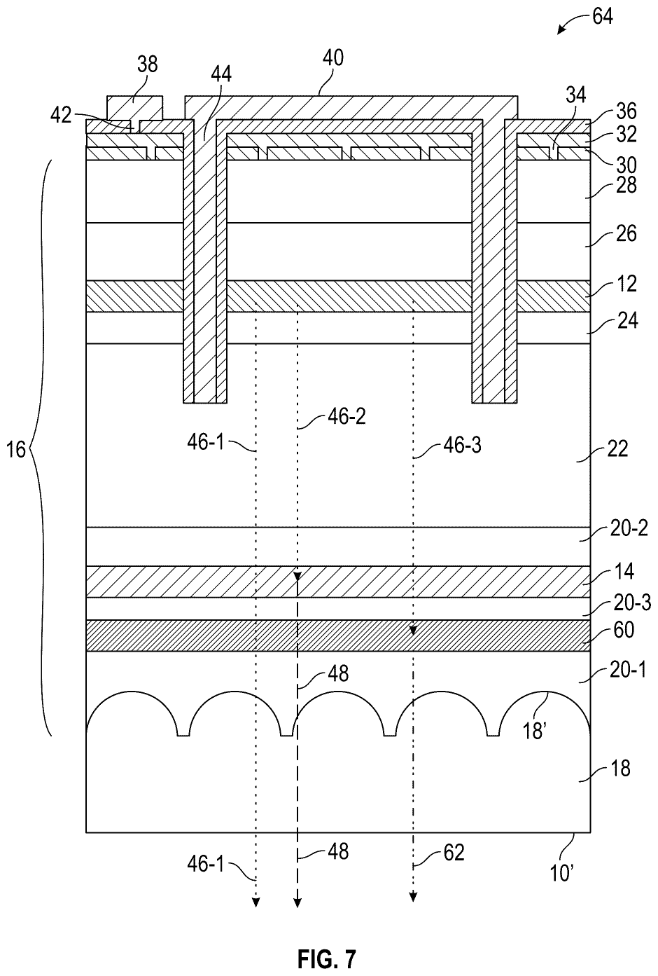

FIG. 7 is a cross-sectional view of a portion of an LED chip 64 that is similar to the LED chip 58 of FIG. 6 for embodiments where the second quantum well structure 14 and the third quantum well structure 60 are separated from one another within the epitaxial structure 16. For example, a third undoped layer 20-3, formed of a same material as the first and second undoped layers 20-1, 20-2 may be formed between the second quantum well structure 14 and the third quantum well structure 60. In certain embodiments, growth temperatures for forming the second quantum well structure 14 and the third quantum well structure 60 are lower than growth temperatures for the undoped layers 20-1 to 20-3. Lower growth temperatures may sometimes lead to increased pit formation or increased amounts of other lattice defects. In this arrangement, the third undoped layer 20-3 may effectively close and/or cover pits and other lattice defects formed by the third quantum well structure 60 to form a smooth surface for subsequent growth of the second quantum well structure 14.

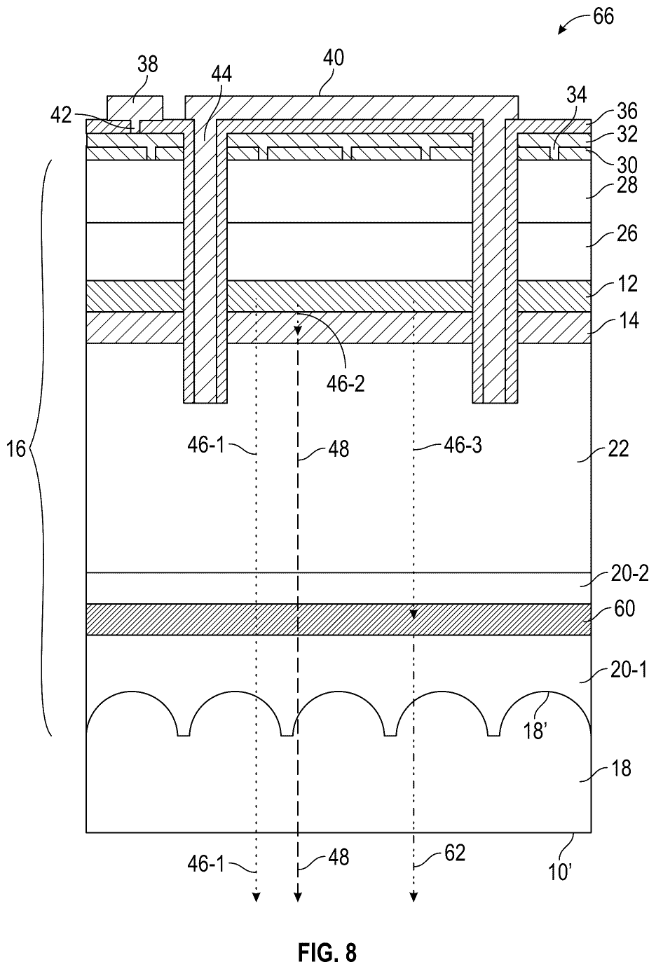

FIG. 8 is a cross-sectional view of a portion of an LED chip 66 that is similar to the LED chip 56 of FIG. 5 for embodiments that include the third quantum well structure 60. In this arrangement, the second quantum well structure 14 is adjacent or even directly contacting the first quantum well structure 12 while the third quantum well structure 60 is positioned elsewhere in the epitaxial structure 16. As illustrated, the third quantum well structure 60 may be positioned between two undoped layers 20-1, 20-2 in a similar manner described above with respect to the LED chip 10 of FIG. 1. Alternatively, the third quantum well structure 60 may be positioned between two doped layers as described above with respect to the LED chip 54 of FIG. 4.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
a substrate;
an n-type layer;
a p-type contact layer;
a first quantum well structure between the n-type layer and the p-type contact layer, the first quantum well structure configured to provide light having a first peak wavelength; and
a second quantum well structure between the first quantum well structure and the substrate, the second quantum well structure configured to absorb a portion of the light having the first peak wavelength and generate light having a second peak wavelength, the second peak wavelength being longer than the first peak wavelength.

2. The LED chip of claim 1, wherein the first quantum well structure comprises a first multiple quantum well and the second quantum well structure comprises a second multiple quantum well.

3. The LED chip of claim 1, wherein the first peak wavelength is in a range from 430 nanometers (nm) to 480 nm, and the second peak wavelength is in a range from 480 nm to 570 nm.

4. The LED chip of claim 1, wherein:
the n-type layer, the p-type contact layer, the first quantum well structure, and the second quantum well structure are part of an epitaxial structure;
the substrate is a growth substrate for the epitaxial structure; and
a surface of the substrate opposite the epitaxial structure forms a primary light-emitting surface.

5. The LED chip of claim 4, wherein:
the first quantum well structure is configured to provide a first emission intensity of the light having the first peak wavelength that exits the primary light-emitting surface;
the second quantum well structure is configured to provide a second emission intensity of the light having the second peak wavelength that exits the primary light-emitting surface; and
the first emission intensity is greater than the second emission intensity.

6. The LED chip of claim 1, further comprising an undoped layer between the second quantum well structure and the n-type layer.

7. The LED chip of claim 6, further comprising an additional undoped layer between the second quantum well structure and the substrate.

8. The LED chip of claim 1, wherein the n-type layer is a first n-type layer that is between the second quantum well structure and the substrate, and a second n-type layer is between the second quantum well structure and the first quantum well structure.

9. The LED chip of claim 8, further comprising an n-contact interconnect that extends through the p-type contact layer, the first quantum well structure, and a portion of the second n-type layer, wherein the second quantum well structure is in a portion of the second n-type layer that is between the first n-type layer and a termination of the n-contact interconnect within the second n-type layer.

10. The LED chip of claim 1, wherein the second quantum well structure forms a superlattice structure for the first quantum well structure.

11. The LED chip of claim 1, further comprising a third quantum well structure between the second quantum well structure and the substrate, wherein the third quantum well structure is configured to absorb a portion of the light having the first peak wavelength and generate light having a third peak wavelength, the third peak wavelength is longer than the first peak wavelength, and the third peak wavelength is different than the second peak wavelength.

12. The LED chip of claim 11, wherein the third quantum well structure and the second quantum well structure are separated by an undoped layer.

13. The LED chip of claim 11, wherein the first peak wavelength is in a range from 430 nanometers (nm) to 480 nm, the second peak wavelength is in a range from 480 nm to 520 nm, and the third peak wavelength is in a range from 520 nm to 570 nm.

14. The LED chip of claim 11, wherein the first peak wavelength is in a range from 430 nanometers (nm) to 450 nm, the second peak wavelength is in a range from 450 nm to 480 nm, and the third peak wavelength is in a range from 480 nm to 570 nm.

15. The LED chip of claim 11, wherein the first peak wavelength is in a range from 100 nanometers (nm) to 400 nm, the second peak wavelength is in a range from 430 nm to 480 nm, and the third peak wavelength is in a range from 480 nm to 570 nm.

16. The LED chip of claim 11, wherein the second quantum well structure forms a superlattice structure for the first quantum well structure, and the third quantum well structure is between the second quantum well structure and the substrate.

17. A light-emitting diode (LED) chip comprising:
an epitaxial structure comprising:
an n-type layer;
a p-type contact layer;
a first quantum well structure between the n-type layer and the p-type contact layer, the first quantum well structure configured to provide light having a first peak wavelength; and
a second quantum well structure configured to absorb a portion of the light having the first peak wavelength and generate light having a second peak wavelength, the second peak wavelength being longer than the first peak wavelength, the first quantum well structure positioned between the p-type contact layer and the second quantum well structure;
a p-contact electrically connected to the p-type contact layer; and
an n-contact electrically connected to the n-type layer, the p-contact and the n-contact being arranged on a same side of the epitaxial structure.

18. The LED chip of claim 17, wherein a primary light-emitting surface of the LED chip is formed on a side of the epitaxial structure that is opposite the p-contact and the n-contact.

19. The LED chip of claim 18, wherein the second quantum well structure is positioned between the primary light-emitting surface and the first quantum well structure.

20. The LED chip of claim 19, further comprising a third quantum well structure between the primary light-emitting surface and the first quantum well structure.
